(19) United States
(12) Patent Application Publication
(10) Pub. No.: US 2024/0136131 A1
(43) Pub. Date: Apr. 25, 2024

(54) LIQUID-COOLING RADIATING PIPE AND VACUUM INTERRUPTER WITH BUILT-IN LIQUID-COOLING RADIATING PIPE

(71) Applicant: Sichuan University, Sichuan (CN)

(72) Inventors: Xiaolong HUANG, Sichuan (CN); Tao SUN, Sichuan (CN); Yiwei JI, Sichuan (CN); Shangyu YANG, Sichuan (CN); Zhiyun WU, Sichuan (CN); Shuangwei ZHAO, Sichuan (CN); Shenli JIA, Sichuan (CN); Lihua ZHAO, Sichuan (CN); Wenjun NING, Sichuan (CN); Zhong WANG, Sichuan (CN); Junwen REN, Sichuan (CN)

(21) Appl. No.: 18/314,345

(22) Filed: May 8, 2023

(30) Foreign Application Priority Data
Oct. 19, 2022 (CN) 202211283708.3

(51) Int. Cl. H01H 33/664; H05K 7/20

(52) U.S. Cl. CPC H01H 33/664; H05K 7/20218

(57) ABSTRACT

The present disclosure relates to a liquid-cooling radiating pipe and a vacuum interrupter with a built-in liquid-cooling radiating pipe, belonging to the field of vacuum circuit breakers. Based on an original structure of an vacuum interrupter, a liquid-cooling radiating pipe of a Tesla valve structure is arranged in a conductive rod of the vacuum interrupter with the built-in liquid-cooling radiating pipe, and liquid metal is used as a circulating coolant in the liquid-cooling radiating pipe, and by using the self-circulating flow of the liquid metal in the pipeline, the capacity of the conductive rod to dissipate heat to the outside is significantly increased, and the problem of excessive internal temperature rise of a vacuum circuit breaker is effectively solved.

### CROSS-REFERENCE TO RELATED APPLICATION

This patent application claims the benefit and priority of Chinese Patent Application No. 202211283708.3, filed with the China National Intellectual Property Administration on Oct. 20, 2022, the disclosure of which is incorporated by reference herein in its entirety.

### TECHNICAL FIELD

The present disclosure relates to the field of vacuum circuit breakers, in particular to a liquid-cooled radiating pipe and a vacuum interrupter with a built-in liquid-cooled radiating tube.

### BACKGROUND

At present, SF₆ circuit breakers and vacuum circuit breakers are the main types of circuit breakers in power systems. SF₆ gas is widely used in high-voltage and ultra-high-voltage fields due to its good thermal stability and electronegativity. However, in view of the strong greenhouse effect of SF₆ gas, it has become a hot research issue for workers in the field of power equipment to replace SF₆ circuit breakers with “environmentally friendly switches”. In contrast, vacuum circuit breakers have minimal environmental pollution and meet environmental requirements, also have numerous advantages such as long mechanical life, compact size, light weight, low noise, simple maintenance, etc., and thus have been widely used in the field of power switches at medium voltages from 3.6 to 40.5 kV. Although vacuum breaking technology has dominated in the medium-voltage level, it faces a series of technical challenges when applied to high-voltage levels, including the problem of overhigh contact temperature of the vacuum circuit breaker when breaking high currents.

As the circuit resistance of vacuum circuit breaker is the main heat source affecting the temperature rise, the circuit resistance of interrupter usually accounts for more than 50% of the circuit resistance of vacuum circuit breaker. The contact resistance of contact gap is the main component of the circuit resistance of vacuum interrupter, this is because a contact system is sealed in the vacuum interrupter, and the heat generated can only be dissipated to the outside through conductive rods. In addition, due to a special structure of the vacuum circuit breaker, the only effective heat transfer mode in vacuum interrupter is heat conduction, while convection heat transfer does not work, and heat radiation is not significant. Meanwhile, due to the consideration of vacuum insulation, conduction/heat conduction paths in the vacuum interrupter are long, thus being not conducive to heat conduction and heat dissipation.

Therefore, during use, internal overheating problem may occur in the vacuum circuit breaker, especially when breaking high currents, due to the own limitations of the vacuum circuit breaker, excessive internal temperature rise may occur in the circuit breaker, which directly affects the safe and stable operation of the equipment. The heating issue in vacuum circuit breaker is a vicious cycle and accumulative process. If such an issue is not addressed and controlled, the temperature will continue to rise, overheating may increase the dielectric loss of insulation parts, accelerate the aging of insulation parts, reduce the insulation grade, and fail the insulation of the circuit breaker in severe cases. At the same time, excessive temperature in the circuit breaker will cause contact material to soften, or cause fusion welding of contacts in severe cases, or potentially lead to breaking failure in extreme cases. The overheating may also cause oxidization on the surface of conductor metal, and the generated oxide increases the contact resistance and affects the circuit resistance of the circuit breaker, resulting in further increase of heat, or causing the circuit breaker to burn out or even explode in severe cases. Moreover, overheating of the circuit breaker is a potential cause of many faults. Therefore, enhancing the heat dissipation capacity of vacuum circuit breakers and solving the internal overheating issue of the vacuum circuit breakers during high current breaking are crucial for promoting the development of vacuum circuit breakers towards high voltages and high current, and have significant practical application value.

### SUMMARY

An objective of the present disclosure is to provide a liquid-cooling radiating pipe and a vacuum interrupter with a built-in liquid-cooling radiating pipe, so as to solve the problems of accelerated aging of insulation parts, softening of contact materials and explosion of a vacuum circuit breaker caused by excessive internal temperature in the vacuum circuit breaker in the prior art.

In order to achieve the above objective, the present disclosure provides the following solution:

A liquid-cooling radiating pipe includes a U-shaped radiating pipe, and a circulating coolant. The U-shaped radiating pipe is filled with the circulating coolant.

Alternatively, the circulating coolant is a liquid metal.

Alternatively, the U-shaped radiating pipe is a of Tesla valve structure.

A vacuum interrupter with a built-in liquid-cooling radiating pipe includes the liquid-cooling radiating pipe above.

Alternatively, the vacuum interrupter with the built-in liquid-cooling radiating pipe further includes an interrupter envelope, two contacts, and two conductive rods.

The liquid-cooling radiating pipe is arranged inside one of the conductive rods, a fluid inlet and a fluid outlet of the liquid-cooling radiating pipe are bother higher than one end surface of the conductive rod.

The contacts and the conductive rods are arranged inside the interrupter envelope, and the contacts, the conductive rods and the interrupter envelope are coaxially arranged.

First end faces of the contacts are connected to second end faces of the conductive rods, and second end faces of the two contacts are opposite to each other.

Alternatively, the vacuum interrupter with the built-in liquid-cooling radiating pipe further includes a shield cover and a bellow.

The shield cover is arranged inside the interrupter envelope, covers side surfaces of the two contacts, and is coaxially arranged with the contacts.

The bellow is sleeved outside another conductive rod and is coaxially arranged with the conductive rod.

According to the specific embodiment provided by the present disclosure, the present disclosure discloses the following technical effects:

According to a liquid-cooling radiating pipe and a vacuum interrupter with a built-in liquid-cooling radiating pipe, the liquid-cooling radiating pipe is arranged inside a conductive rod of the vacuum interrupter, the liquid-cooling radiating pipe is U-shaped, and is filled with a circulating coolant. The heat energy of the conductive rod and a contact is absorbed by the circulating coolant, thereby achieving the purpose of reducing the temperature rise in the vacuum interrupter, reducing the internal temperature of the vacuum circuit breaker, and avoiding the problems of accelerated aging of insulation parts, softening of contact materials and explosion of the vacuum circuit breaker.

### BRIEF DESCRIPTION OF THE DRAWINGS

To describe the technical solutions in the embodiments of the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a structure schematic diagram of a vacuum interrupter with a built-in liquid-cooling radiating pipe in accordance with the present disclosure;

FIG. 2 is a partial enlarged view of a liquid-cooling radiating pipe in accordance with the present disclosure;

FIG. 3 is a schematic diagram of an internal fluid flow direction of a Tesla valve structure in accordance with the present disclosure;

FIG. 4 is a self-circulating flow diagram of a liquid metal in accordance with the present disclosure in a liquid-cooling radiating pipe.

In the drawings: 1-interrupter envelope, 2-contact, 3-conductive rod, 4-shield cover, 5-bellow, 6-liquid-cooling radiating pipe.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts shall fall within the protection scope of the present disclosure.

An objective of the present disclosure is to provide a liquid-cooling radiating pipe and a vacuum interrupter with a built-in liquid-cooling radiating pipe, so as to solve the problems of accelerated aging of insulation parts, softening of contact materials and explosion of a vacuum circuit breaker caused by excessive internal temperature in the vacuum circuit breaker in the prior art.

Based on enhancing the heat dissipation capacity of conductive rods, a new method for reducing internal temperature rise of a vacuum circuit breaker is provided. That is, on the basis of an original structure of the existing vacuum circuit breaker, a liquid-cooling radiating pipe of a Tesla valve structure is arranged in a conductive rod, and a liquid metal is used as circulating coolant in the liquid-cooling radiating pipe. By using the self-circulating flow of the liquid metal in the pipeline, the capacity of the conductive rod to dissipate heat to the outside is significantly increased, and the problem of excessive internal temperature rise of the vacuum circuit breaker is effectively solved.

To make the above objectives, features and advantages of the present disclosure more apparently and understandably, the present disclosure is further described in detail below with reference to the accompanying drawings and specific embodiments.

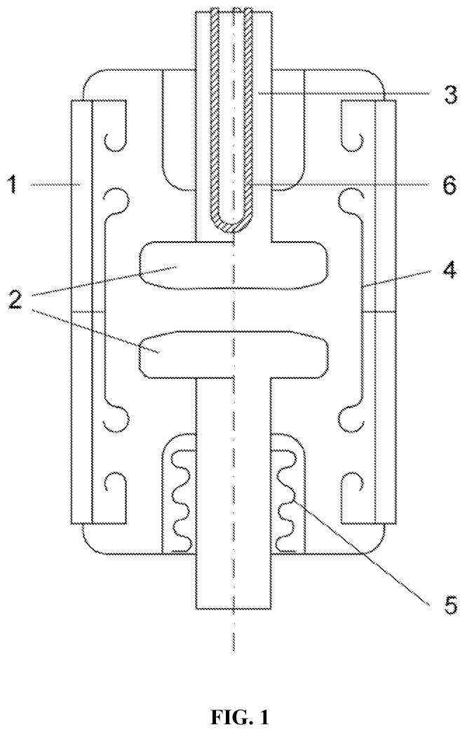

It is provided a vacuum interrupter with a built-in liquid-cooling radiating pipe according to the present disclosure. As shown in FIG. 1, the vacuum interrupter with the built-in liquid-cooled radiating pipe includes an interrupter envelope 1, two contacts 2, two conductive rods 3, a shield cover 4, and a bellow 5. The above components are the basic structure of the vacuum interrupter of a vacuum circuit breaker. The vacuum circuit breaker can achieve the breaking and connection of a circuit through the separation and closure of the contacts 2. The contacts 2 and the conductive rods 3 are main heat sources in the vacuum interrupter, and the heat is mainly dissipated to the outside through heat conduction of the conductive rods 3.

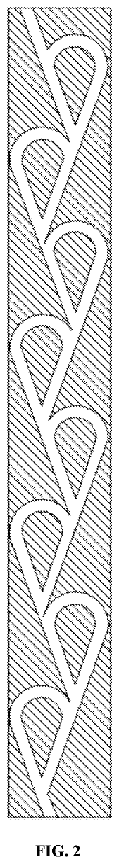

In order to enhance the heat dissipation efficiency of the conductive rods 3 and reduce the internal temperature rise of the vacuum circuit breaker, a liquid-cooling radiating pipe 6 is required. Therefore, it is also provided a liquid-cooling radiating pipe 6 according to the present disclosure. The liquid-cooling radiating pipe 6 is U-shaped, and the liquid-cooling radiating pipe 6 is arranged inside one of the conductive rods 3 of the vacuum interrupter in a manner of grooving inside the metal, and a liquid metal is used as a circulating coolant in the liquid-cooling radiating pipe 6. In addition, the liquid-cooling radiating pipe 6 is of a Tesla valve structure, as shown in FIG. 2.

A fluid inlet and a fluid outlet of the liquid-cooling radiating pipe 6 are bother higher than first end surfaces of the conductive rods 3. The first end faces of the conductive rods 3 are end faces of the conductive rods 3 exposed outside the interrupter envelope 1, and second end faces of the conductive rods 3 are end faces of the conductive rods 3 inside the interrupter envelope 1.

The contacts 2 and the conductive rods 3 are arranged inside the interrupter envelope 1, and the contact 2, the conductive rods 3 and the interrupter envelope 1 are coaxially provided. First end faces of the contacts 2 are connected to the second end faces of the conductive rods 3, and the second end faces of the two contacts 2 are opposite to each other.

The shield cover 4 is arranged inside the interrupter envelope 1, covers side surfaces of the two contacts 2, and is coaxially arranged with the contacts 2. The bellow 5 is sleeved outside another conductive rod 3 and is coaxially arranged with the conductive rod 3.

A liquid metal is used as a cooling medium of the liquid-cooling radiating pipe 6. The liquid metal is a nontoxic metal mixture with a low melting point, which can be melted into a liquid state at room temperature, and includes some low melting point metals, such as gallium or indium. The liquid metal has unique physical properties, including both fluidity of liquid and excellent thermal conductivity of metal; and the thermal conductivity of the liquid metal is generally in the order of 10 W·m−1·K−1, which is 50 times that of water and more than 1000 times that of air, and thus the liquid metal has good convective heat transfer ability. As a metal mixture, the liquid metal also has high conductivity property, which has little influence on the conductivity of the conductive rods 3 and the resistance value of the conductive loop. Moreover, compared with water cooling, the liquid metal is less prone to boiling, leakage and evaporation problems due to its high boiling point, high surface tension and low saturated vapor pressure, and is safer and more stable. The liquid metal has a high density and can accommodate a large number of nanoparticles, and thus carbon nanotubes and three typical high-thermal conductivity metal nanoparticles (e.g., gold, silver, copper) can be added into the liquid metal to further enhance the physical properties of liquid metal such as thermal conductivity, thus making the liquid metal have better adaptability. Compared with the traditional air-cooling radiating system and liquid-cooling radiating system, the novel radiating system with the liquid metal as a heat transfer medium has better heat dissipation capacity, safer structure and material properties and more efficient circulation system due to its high thermal conductivity, low viscosity and stable physical properties.

The liquid-cooling radiating pipe 6 of a special Tesla valve structure is adopted. Considering a small internal space and high insulation requirements of the vacuum circuit breaker, it is not suitable to use the traditional active pump as a device to drive the cooling medium to circulate in the radiating pipe. Therefore, the liquid-cooling radiating pipe 6 of the Tesla valve structure can passively drive the liquid metal to circulate in the liquid-cooling radiating pipe 6, which benefits from the special structural characteristics of the Tesla valve, and the unidirectional flow of fluids such as liquid and gas is ensured.

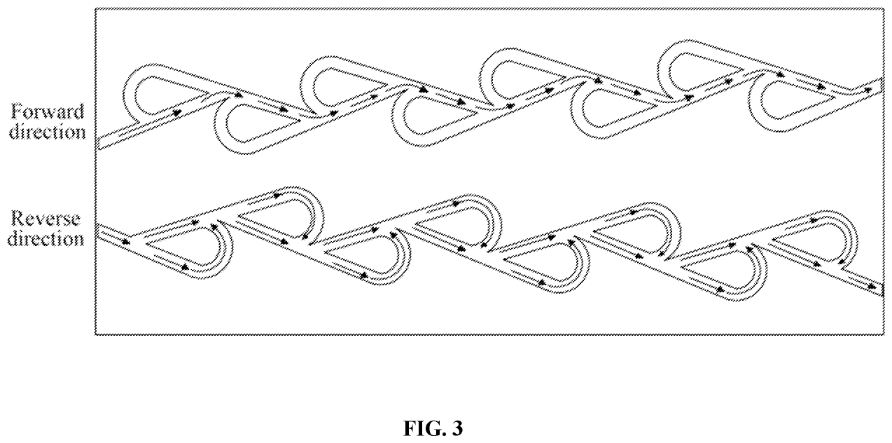

As shown in FIG. 3, as the Tesla valve employs a special loop design, when the fluid (liquid metal) flows through Tesla valve in a forward direction, the fluid may be split into two paths at each intersection, and then the two paths of fluid may converge at the next intersection to accelerate. On the contrary, if the fluid flows into the Tesla valve in a reverse direction, the fluid may also be split into two paths at a first intersection and converge again at a second intersection, and the difference is that a great resistance is formed as the flow directions of the two paths are opposite in this time. Therefore, the fluid can flow through the Tesla valve only in the forward direction, and is hard to flow into the Tesla valve in a reverse direction.

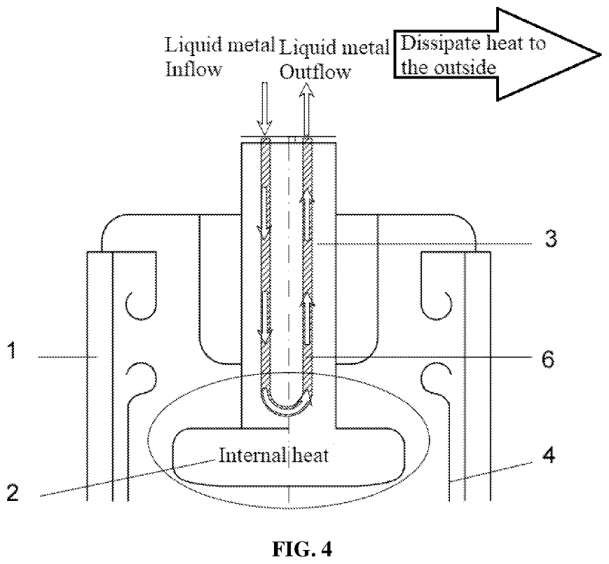

The characteristic of Tesla valve is that for reverse passing, the greater the pressure, the greater the resistance, the slower the speed and even complete stop. For forward passing, the greater the pressure, the faster the speed. During the operation of the vacuum circuit breaker, the internal heat of the vacuum interrupter may cause both left and right radiating pipes to have thermal driving force from a high-temperature area to a low-temperature area. Due to the special structure of the Tesla valve, the flowing resistance of the liquid metal in the left and right radiating pipes is different, which facilitates the liquid metal in the radiating pipe flow unidirectionally in the direction with low flow resistance, and thus the self-circulating flow of the liquid metal can be achieved in the liquid-cooled radiating pipe 6 in a passive manner. As shown in FIG. 4, the internal heat of the vacuum interrupter is conducted to the outside of the interrupter, which greatly improves the heat dissipation efficiency of the conductive rods 3 and effectively solves the problem of excessive internal temperature rise of the vacuum circuit breaker.

The vacuum interrupter with the built-in liquid-cooling radiating pipe in accordance with the present disclosure has the following advantages:
1. The liquid metal is used as a circulating cooling medium, which has high thermal conductivity, low viscosity, good electrical conductivity and stable physical properties. Compared with the traditional air-cooling radiating system and liquid-cooling radiating system, the liquid metal has better cooling ability, and thus the heat dissipation efficiency of the conductive rods of the vacuum interrupter is significantly improved, and the problem of excessive internal temperature rise of the vacuum circuit breaker can be effectively solved.
2. The liquid-cooling radiating pipe installed in the vacuum interrupter is of a Tesla valve structure, depending on the structural characteristics of the Tesla valve, the self-circulating flow of the liquid metal in the liquid-cooling radiating pipe of the conductive rod can be achieved without additional power supply drive device. Therefore, the liquid-cooling radiating pipe is more suitable for the internal compact space of the vacuum interrupter, and cannot affect the insulation performance of the vacuum breaker.

Embodiments in this specification are described in a progressive manner, each embodiment focuses on differences from other embodiments, and the same and similar parts between the embodiments can be referred to each other.

Several examples are used for illustration of the principles and implementation methods of the present disclosure. The description of the embodiments is merely used to help illustrate the method and its core principles of the present disclosure. In addition, those of ordinary skill in the art can make various modifications in terms of specific embodiments and scope of application in accordance with the teachings of the present disclosure. In conclusion, the content of this specification shall not be construed as a limitation to the present disclosure.

What is claimed is:

1. A liquid-cooling radiating pipe, comprising a U-shaped radiating pipe and a circulating coolant, wherein the U-shaped radiating pipe is filled with the circulating coolant.

2. The liquid-cooling radiating pipe according to claim 1, wherein the circulating coolant is a liquid metal.

3. The liquid cooled radiating pipe according to claim 1, wherein the U-shaped radiating pipe is of a Tesla valve structure.

4. A vacuum interrupter with a built-in liquid-cooling radiating pipe, wherein the vacuum interrupter with the built-in liquid-cooling radiating pipe comprises the liquid-cooling radiating pipe according to claim 1.

5. The vacuum interrupter with a built-in liquid-cooling radiating pipe according to claim 4, wherein the circulating coolant is a liquid metal.

6. The vacuum interrupter with a built-in liquid-cooling radiating pipe according to claim 4, wherein the U-shaped radiating pipe is of a Tesla valve structure.

7. The vacuum interrupter with a built-in liquid-cooling radiating pipe according to claim 4, wherein the vacuum interrupter with the built-in liquid-cooling radiating pipe further comprises an interrupter envelope, two contacts, and two conductive rods;
the liquid-cooling radiating pipe is arranged inside one of the conductive rods, a fluid inlet and a fluid outlet of the liquid-cooling radiating pipe are bother higher than one end surface of the conductive rod;
the contacts and the conductive rods are arranged inside the interrupter envelope, and the contacts, the conductive rods and the interrupter envelope are coaxially provided; and
first end faces of the contacts are connected to second end faces of the conductive rods, and second end faces of the two contacts are opposite to each other.

8. The vacuum interrupter with a built-in liquid-cooling radiating pipe according to claim 5,
wherein the vacuum interrupter with the built-in liquid-cooling radiating pipe further comprises an interrupter envelope, two contacts, and two conductive rods;
the liquid-cooling radiating pipe is arranged inside one of the conductive rods, a fluid inlet and a fluid outlet of the liquid-cooling radiating pipe are bother higher than one end surface of the conductive rod;
the contacts and the conductive rods are arranged inside the interrupter envelope, and the contacts, the conductive rods and the interrupter envelope are coaxially provided; and
first end faces of the contacts are connected to second end faces of the conductive rods, and second end faces of the two contacts are opposite to each other.

9. The vacuum interrupter with a built-in liquid-cooling radiating pipe according to claim 6, wherein the vacuum interrupter with the built-in liquid-cooling radiating pipe further comprises an interrupter envelope, two contacts, and two conductive rods;
the liquid-cooling radiating pipe is arranged inside one of the conductive rods, a fluid inlet and a fluid outlet of the liquid-cooling radiating pipe are bother higher than one end surface of the conductive rod;
the contacts and the conductive rods are arranged inside the interrupter envelope, and the contacts, the conductive rods and the interrupter envelope are coaxially provided; and
first end faces of the contacts are connected to second end faces of the conductive rods, and second end faces of the two contacts are opposite to each other.

10. The vacuum interrupter with a built-in liquid-cooling radiating pipe according to claim 7, wherein the vacuum interrupter with the built-in liquid-cooling radiating pipe further comprises a shield cover and a bellow;
the shield cover is arranged inside the interrupter envelope, covers side surfaces of the two contacts, and is coaxially arranged with the contacts; and
the bellow is sleeved outside another conductive rod and is coaxially arranged with the conductive rod.

11. The vacuum interrupter with a built-in liquid-cooling radiating pipe according to claim 8, wherein the vacuum interrupter with the built-in liquid-cooling radiating pipe further comprises a shield cover and a bellow;
the shield cover is arranged inside the interrupter envelope, covers side surfaces of the two contacts, and is coaxially arranged with the contacts; and
the bellow is sleeved outside another conductive rod and is coaxially arranged with the conductive rod.

12. The vacuum interrupter with a built-in liquid-cooling radiating pipe according to claim 9, wherein the vacuum interrupter with the built-in liquid-cooling radiating pipe further comprises a shield cover and a bellow;
the shield cover is arranged inside the interrupter envelope, covers side surfaces of the two contacts, and is coaxially arranged with the contacts; and
the bellow is sleeved outside another conductive rod and is coaxially arranged with the conductive rod.
